(19) United States
(12) Patent Application Publication
(10) Pub. No.: US 2017/0227584 A1
(43) Pub. Date: Aug. 10, 2017

(54) TIME-SERIES DATA WAVEFORM ANALYSIS DEVICE, METHOD THEREFOR AND NON-TRANSITORY COMPUTER READABLE MEDIUM

(71) Applicant: KABUSHIKI KAISHA TOSHIBA, Tokyo (JP)

(72) Inventors: Daiki SUEHIRO, Kawasaki (JP); Toshiaki OHGUSHI, Yokohama (JP)

(21) Appl. No.: 15/261,165

(22) Filed: Sep. 9, 2016

(30) Foreign Application Priority Data
Feb. 5, 2016 (JP) 2016-021313

(51) Int. Cl. G01R 23/167; G01R 23/18

(52) U.S. Cl. CPC G01R 23/167; G01R 23/18

(57) ABSTRACT

According to one embodiment, a time-series data waveform analysis device implemented by a computer including at least one hardware processor is provided. The hardware processor configured to: add a shapelet being a part of a partial time series included in labeled time-series data to a shapelet set; randomly extract one or more labeled time-series data and calculate a feature value of the shapelet for the extracted labeled time-series data according to a TSS method; update a parameter, which includes the shapelet and a weight coefficient for the shapelet, based on the feature value according to a stochastic gradient descent method; remove the shapelet, the corresponding weight coefficient of which is 0, from the shapelet set; and create an evaluation function based on the shapelet in the shapelet set and the weight coefficient.

### CROSS-REFERENCE TO RELATED APPLICATIONS

This application is based upon and claims the benefit of priority from Japanese Patent Application No. 2016-021313, filed on Feb. 5, 2016; the entire contents of which are incorporated herein by reference.

### FIELD

Embodiments described herein relate to a time-series data waveform analysis device, a method therefor and a non-transitory computer readable medium.

### BACKGROUND

In recent years, the technique of analyzing a waveform of time-series data has been becoming important in various fields such as economic time series analysis and in-plant manufacturing process sensor monitoring. This technique is used for, e.g., classification, prediction and scoring (hereinafter referred to as “classification, etc.”) of time-series data.

As methods for analyzing a waveform of time-series data, time series shapelets methods (hereinafter referred to as “TSS method(s)”) are drawing attention. Use of a TSS method is reported to enable high-accurate analysis. In a TSS method, based on a plurality of time-series data for learning, an evaluation function including feature values of shapelets and weight coefficients of the feature values is created, and classification, etc., of the time-series data are performed using the evaluation function.

In conventional TSS methods, where “Q” is the total shapelet candidate count, “N” is the number of time-series data and “L” is a length of each time-series data (time series length), a calculation amount for creating an evaluation function is “O” (Q×N×L×L). The total candidate count “Q” is the total number of partial time series can be created from the time-series data and thus is enormous. Also, the calculation amount Increases directly with the square of the time series length. As a result, with the conventional TSS methods, the calculation amount is large, which may result in difficulty in real-time calculation.

In order to reduce the calculation amount, a method in which “K” (K<<Q) shapelet candidates are provided in advance has been proposed. According to this method, the calculation amount is “O” (K×N×L×L). However, this method has a problem in that if the provided shapelet candidates are improper, a converged solution of an objective function for obtaining an evaluation function is not obtained, resulting in failure to obtain an evaluation function.

### BRIEF DESCRIPTION OF THE DRAWINGS

FIG. 1 is a diagram illustrating an example of a functional configuration of a time-series data waveform analysis device according to a first embodiment;

FIG. 2 is a diagram illustrating an example of a labeled data set;

FIG. 3 is a diagram illustrating an example of a feature value calculation method;

FIG. 4 is a diagram illustrating an example of a computer;

FIG. 5 is a flowchart Illustrating an example of evaluation function creation processing according to the first embodiment;

FIG. 6 is a diagram illustrating a functional configuration of a time-series data waveform analysis device according to a 30 second embodiment; and

FIG. 7 is a flowchart illustrating a partial time series addition processing according to the second embodiment.

### DETAILED DESCRIPTION

According to one embodiment, a time-series data waveform analysis device implemented by a computer including at least one hardware processor is provided.

The hardware processor is configured to add a shapelet being a part of a partial time series included in labeled time-series data to a shapelet set.

The hardware processor is configured to randomly extract one or more labeled time-series data and calculate a feature value of the shapelet for the extracted labeled time-series data according to a TSS method.

The hardware processor is configured to update a parameter, which includes the shapelet and a weight coefficient for the shapelet, based on the feature value according to a stochastic gradient descent method.

The hardware processor is configured to remove the shapelet, the corresponding weight coefficient of which is 0, from the shapelet set.

The hardware processor is configured to create an evaluation function based on the shapelet in the shapelet set and the weight coefficient.

Embodiments of the present Invention will be described below with reference to the drawings.

### First Embodiment

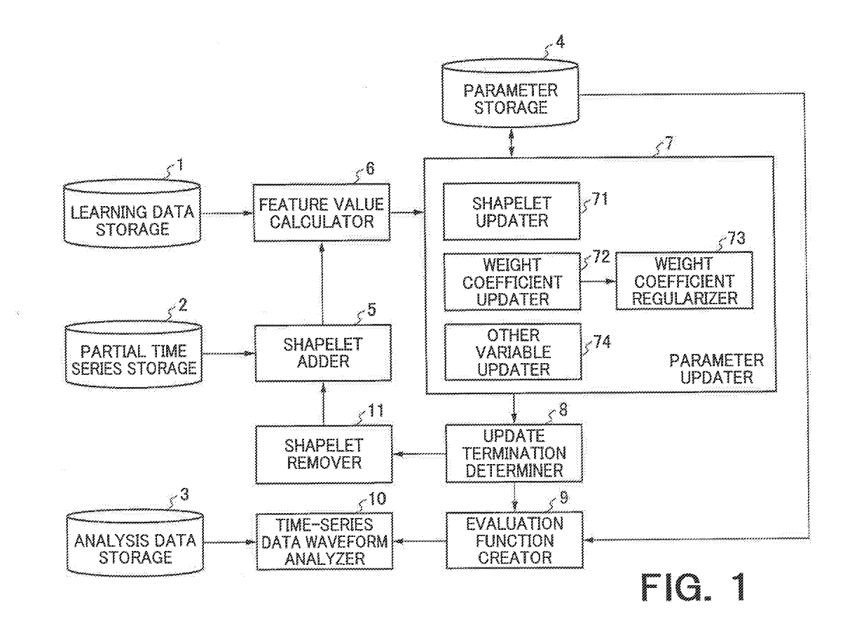

A time-series data waveform analysis device (hereinafter referred to as “analysis device”) according to a first embodiment will be described with reference to FIGS. 1 to 5. First, an overview of a time-series data shapelet analysis method (hereinafter referred to as “analysis method”) using an analysis device according to the present embodiment will be described.

In the present embodiment, first, as inputs to the analysis device, time-series data for learning, a partial time series set, and objective function parameters are provided. The analysis device randomly extracts “K” partial time series from the partial time series set as shapelets. The analysis device calculates feature values of the respective shapelets in the respective time-series data based on the extracted shapelets and the time-series data for learning. The analysis device obtains a solution of an objective function having desired restrictions (optimization problem) based on the obtained feature values to calculate an optimum shapelet and an optimum weight coefficient. In the present embodiment, the optimum solution of the objective function can be obtained by a stochastic gradient descent method. The analysis device creates an evaluation function including the optimum shapelet and weight coefficient obtained as stated above, and performs classification, etc., of time-series data for analysis using the created evaluation function.

Next, a functional configuration of the analysis device according to the present embodiment will be described. FIG. 1 is a diagram Illustrating an example of a functional configuration of the analysis device according to the present embodiment. The analysis device in FIG. 1 includes a learning data storage 1, a partial time series storage 2, an analysis data storage 3, a parameter storage 4, a shapelet adder 5, a feature value calculator 6, a parameter updater 7, an update termination determiner 8, an evaluation function creator 9, a time-series data waveform analyzer 10 and a shapelet remover 11.

The learning data storage 1 stores a labeled data set “T” as learning data for creating an evaluation function. FIG. 2 is a diagram illustrating an example of the labeled data set “T”. As illustrated in FIG. 2, the labeled data set “T” is a set of “N” labeled time-series data “tᵢ” (I=1 to N) (hereinafter referred to as “time-series data tᵢ”). Each time-series data “tᵢ” is time-series data having a time series length of “Lᵢ” with a label provided thereto. The time series lengths “Lᵢ” of the time-series data “tᵢ” Included in the labeled data set “T” may be identical to or different from one another.

In the example in FIG. 2, each time-series data “tᵢ” is provided with a binary integer (+1 or −1) as a label. In the below, it is assumed that the number of time-series data “tᵢ” provided with a label of +1 is “a”, and the number of time-series data “tᵢ” provided with a label of −1 is “b” (a+b=N).

In the present embodiment, an evaluation function created by the analysis device is a function for, for example, calculating a score (evaluation value) according to an estimated label, for time-series data whose label is unknown. More specifically, the evaluation function is a function according to which a high (or low) score for time-series data whose label is estimated to be +1 is calculated and a low (or high) score for time-series data whose label is estimated to be −1 is calculated.

Also, the evaluation function may be a function according to which a label of time-series data, the label being estimated based on a calculated score, is output. In this case, it is possible that the evaluation function may compare a score of time-series data with a threshold value to output a label according to a result of the comparison.

In the present embodiment, there may be three or more kinds of labels to be provided to the time-series data “tᵢ” and the labels may be arbitrary real values. The below description will be provided taking a case where the labeled data set “T” in FIG. 2 is stored in the learning data storage 1, as an example.

The partial time series storage 2 stores a partial time series set “G”. The partial time series set “G” is a set of “Q” partial time series “gᵢ” (i=1 to Q). The respective partial time series “gᵢ” are arbitrary partial time series having a time series length “rᵢ”, extracted from the respective time-series data “tᵢ” included in the labeled data set “T”. The time series lengths “rᵢ” of the respective partial time series “gᵢ” Included in the partial time series set “G” may be identical to or different from one another. In the present embodiment, the partial time series set “G” is provided in advance as shapelet candidates in a TSS method. For example, the partial time series set “G” may be a set of all partial time series of learning data, or if there is learning data that is similar to learning data subjected to analysis before in the present analysis device, shapelets output in the analysis may be provided as shapelet candidates for learning data this time.

The analysis data storage 3 stores unlabeled time-series data, which are objects to be analyzed using an evaluation function, as analysis data. The analysis device estimates scores and labels of the unlabeled time-series data using an evaluation function. Consequently, the analysis device can perform classification, etc., of the unlabeled time-series data.

The parameter storage 4 stores various types of parameters for creating an evaluation function. The parameters stored in the parameter storage 4 will be described in detail later.

The shapelet adder 5 (hereinafter referred to as “adder 5”) randomly extracts “K” (<<Q) partial time series “gⱼ” from the partial time series set “G” and adds the “K” partial time series to a shapelet set “S”. The shapelet set “S” is a set of “K” shapelets “sᵢ” (i=1 to K). The partial time series “g” added to the shapelet set “S” are treated as shapelets “s” in the subsequent processing.

The feature value calculator 6 randomly extracts time-series data “t” from the labeled data set “T” and calculates a feature value vector “X” for each of the extracted time-series data “t”. The feature value vector “X” is a vector including feature values “xₛⱼ” of respective shapelets “sⱼ” in the time-series data “t”, as elements.

Here, a method for calculating a feature value “x” will be described. A feature value “x” In the present embodiment is a value according to a distance between time-series data “t” and a shapelet “s” In the TSS method. More specifically, a feature value “x” is a value resulting from a distance between a shapelet “s” having a time series length “r” and a partial time series “gₛ” included in the time-series data “t” being divided by the time series length “r”. The partial time series “gₛ” is a partial time series having the time series length r and matches with the shapelet “s” (average distance between the partial time series and the shapelet s is smallest) from among the partial time series included in the time-series data “t”. The feature value “x” is expressed by the below expression.

[Expression 1]

x=1/r×(gₛ−s)²=1/r×mingεG(Σ(g−s)²) (1)

In Expression (1), “g” is a partial time series included in the time-series data “t”, and “G” is a set of partial time series in the time-series data “t”. As can be understood from Expression (1), a feature value “x” corresponds to an average distance between a shapelet “s” and a partial time series “gₛ” Included in the time-series data “t”. In other words, a feature value “x” corresponds to a minimum value of an average distance between a shapelet “s” and time-series data “t”.

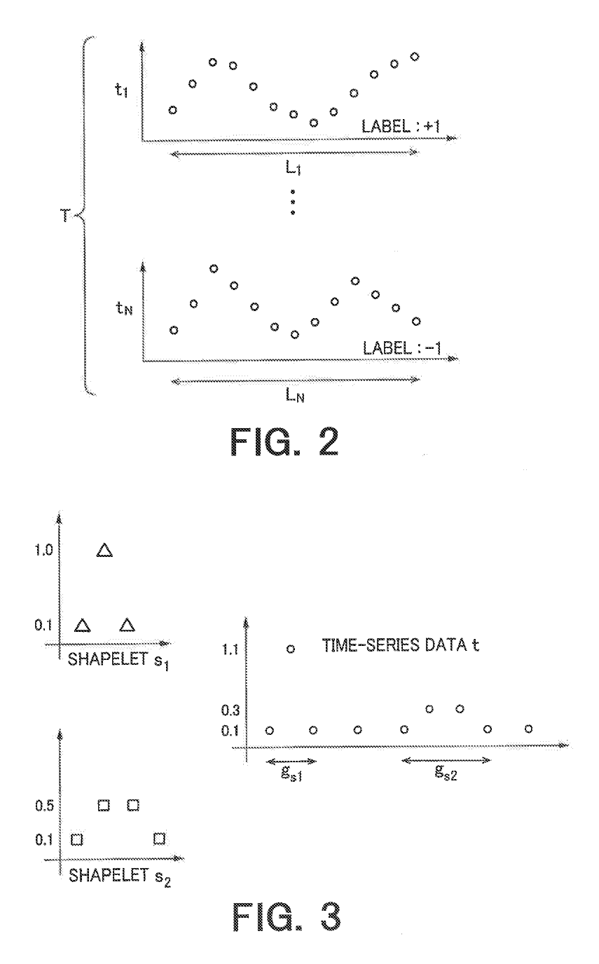

Here, FIG. 3 is a diagram Illustrating a specific example of a method for calculating a feature value “x”. In the example in FIG. 3, two shapelets “s₁”, “s₂” and time-series data “t” are provided. The shapelet “s₁” Includes three piece of data (0.1, 1.0, 0.1: the time series length is 3), and the shapelet “s₂” Includes four piece of data (0.1, 0.5, 0.5, 0.1: the time series length is 4), and time-series data “t” Include nine piece of data (0.1, 1.1, 0.1, 0.1, 0.1, 0.3, 0.3, 0.1, 0.1).

In this case, a partial time series “gₛ₁” In the time-series data “t”, the partial time series “gₛ₁” corresponding to the shapelet “S₁”, is a partial time series including the first to third data in the time-series data “t”, and a feature value “xₛ₁” of the shapelet “s₁” is 0.003 (=⅓×{(0.1−0.1)²+(1.1-1.0)²+(0.1−0.1)²}).

Also, a partial time series “gₛ₂” in the time-series data “t”, the partial time series “gₛ₂” corresponding to the shapelet “s₂”, is a partial time series including the fifth to eighth data in the time-series data “t”, and a feature value “xₛ₂” of the shapelet “s₂” is 0.02 (=¼×{(0.1−0.1)²+(0.3−0.5)²+(0.3-0.5)²+(0.1−0.1)²}).

In the present embodiment, the feature value calculator 6 calculates feature values “xₛⱼ” of the “K” shapelets “sⱼ” (j=1 to K) for the time-series data “t” as described above. Accordingly, the feature value vector “X” of the time-series data “t” is a vector including “K” feature values “xₛⱼ” as elements.

The parameter updater 7 updates various parameters for an evaluation function “f” based on the parameters stored in the parameter storage 4 and the feature value vector “X” of the time-series data “t”. The parameter updater 7 stores each of the updated parameters into the parameter storage 4.

In the present embodiment, the evaluation function “f” is expressed by a linear function including feature values “xₛᵢ” (i=1 to K) of respective shapelets and weight coefficients “wₛᵢ” of the respective feature values “xₛᵢ”. The evaluation function “f” is expressed by, for example, the Inner product of the feature value vector “X” and a weight vector “W” (f=X·W). The weight vector “W” is a vector including the weight coefficients “wₛᵢ” (i=1 to K) as elements.

More specifically, the parameter updater 7 updates the weight vector “W” (weight coefficients “w”) and the shapelet set “S” (shapelets “s”) using the stochastic gradient descent method and obtains a solution of the objective function. The evaluation function “f” is formed by the weight vector “W” and the shapelet set “S” updated by the parameter updater 7. The parameter updater 7 includes a shapelet updater 71, a weight coefficient updater 72, a weight coefficient regularizer 73 and another variable updater 74.

The shapelet updater 71 calculates a gradient of each shapelet “s” and updates the shapelet “s” based on the obtained gradient. Consequently, the shapelet set “S” is updated. A method for updating a shapelet “s” will be described in detail later.

The weight coefficient updater 72 calculates a gradient of each weight coefficient “w” and updates the weight coefficient “w” based on the obtained gradient. Consequently, the weight vector “W” is updated. A method for updating a weight coefficient “w” will be described in detail later.

The weight coefficient regularizer 73 (hereinafter referred to as “regularizer 73”) regularizes the weight vector “W” updated by the weight coefficient updater 72, based on a regularization condition included in the objective function. For example, the regularizer 73 can map the weight vector “W” in a space of ∥W∥₁≦λ using an L1 spatial mapping algorithm. Here, an amount of calculation for the regularization is around “O” (K). Details of the L1 spatial mapping algorithm are as described in the below document.
Reference: J. Duchl et al., Efficient Projections onto the |1-ball for Learning in High Dimensions

Here, a method for regularizing the weight vector “W” is not limited to the above method and can arbitrarily be selected. A user of the analysis device can set a desired regularization condition.

The other variable updater 74 calculates gradients of other variables included in the objective function and updates the other variables based on the obtained gradients. The other variables are optimization objects, except the shapelet set “S” and the weight vector “W”, included in the objective function. If no other variables are included in the objective function, the other variable updater 74 is unnecessary. A method for updating another variable will be described in detail later.

The update termination determiner 8 (hereinafter referred to as “determiner 8”) determines whether or not to terminate an update of a parameter. More specifically, the determiner 8 determines whether or not an update termination condition is satisfied. The update termination condition is set according to, for example, the number of updates. In this case, upon the number of updates by the parameter updater 7 reaching a predetermined count, the determiner 8 makes a determination to terminate the update. As described above, the update termination condition is set according to the number of updates, enabling time required for processing for creating an evaluation function “f” to be set within a desired range.

Also, the update termination condition may be set according to a prediction accuracy of the obtained evaluation function “f”. In this case, the determiner 8 acquires a plurality of time-series data “t” from the learning data storage 1, labels of the obtained time-series data “t” are predicted according to the evaluation function “f” Including the shapelet set “S” and the weight vector “W” updated by the label parameter updater 7. If an accuracy rate of the predicted labels is no less than a predetermined value, the determiner 8 makes a determination to terminate the update. As described above, the update termination condition is set according to a prediction accuracy, ensuring prediction accuracy of the evaluation function “f”.

The evaluation function creator 9 creates an evaluation function “f” based on the respective parameters stored in the parameter storage 4. The evaluation function “f” is expressed by, for example, the Inner product of the weight vector “W” and the feature value vector “X” for the shapelet set “S” (f=W·X=wᵢxᵢ (i=1 to K)).

The time-series data waveform analyzer 10 (hereinafter referred to as “analyzer 10”) analyzes analysis data based on the evaluation function “f” created by the evaluation function creator 9. In other words, the analyzer 10 performs classification, etc., of unlabeled time-series data.

The shapelet remover 11 (hereinafter referred to as “remover 11”) removes shapelets “s”, corresponding weight coefficients “w” of which are 0 from the shapelet set “S” If the determiner 8 makes a determination not to terminate the update (to continue the update). It is assumed that the number of shapelets s removed by the remover 11 is “k”. As a result of the remover 11 removing “k” shapelets “s”, the number of shapelets “s” Included in the shapelet set “S” is (K−k).

Upon removal of the “k” shapelets “s” by the remover 11, the adder 5 newly extracts “k” partial time series “g” from the partial time series storage 2 and adds the “k” partial time series “g” to the shapelet set “S” as shapelets “s”. Subsequently, parameter update processing is performed based on the new shapelet set “S”.

Next, a hardware configuration of the analysis device according to the present embodiment will be described. The analysis device according to the present embodiment includes a computer 100. Examples of the computer 100 include, e.g., a server, a client, a microcomputer and a general-purpose computer.

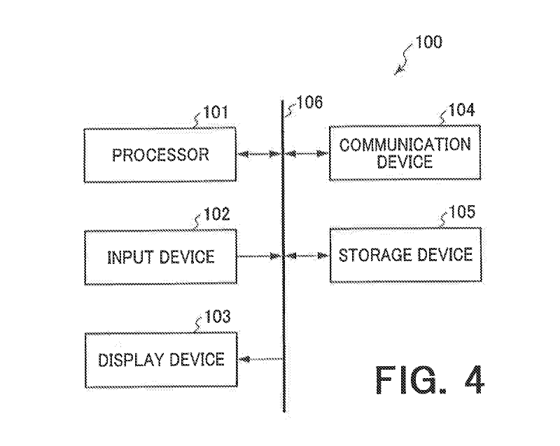

FIG. 4 is a diagram Illustrating an example of the computer 100. The computer 100 in FIG. 4 includes a processor 101, an input device 102, a display device 103, a communication device 104 and a storage device 105. The processor 101, the input device 102, the display device 103, the communication device 104 and the storage device 105 are interconnected via a bus 106.

The processor 101, which is a hardware processor or processing circuitry, is an electronic circuit including a control device and an arithmetic operation device of the computer 100. For the processor 101, for example, a general-purpose processor, a central processing unit (CPU), a microprocessor, a digital signal processor (DSP), a controller, a microcontroller, a state machine, an application-specific integrated circuit, a field programmable gate array (FPGA), programmable logic device (PLD) or any combination thereof can be used.

The processor 101 performs arithmetic operation processing based on data and a program Input from respective devices (for example, the input device 102, the communication device 104 and the storage device 105) connected thereto via the bus 106 and outputs arithmetic operation results and control signals to respective devices (for example, the display device 103, the communication device 104 and the storage device 105) connected thereto via the bus 106. More specifically, the processor 101 executes, e.g., an OS (operation system) of the computer 100 and a time-series data shapelet analysis program (hereinafter referred to as “analysis program”) and controls the respective devices included in the computer 100.

The analysis program is a program that causes the computer 100 to provide the above-described functional configuration of the analysis device. The analysis program is stored in a non-temporary, physical computer-readable storage medium. Examples of the storage medium include, but not limited to, an optical disc, a magnetooptical disk, a magnetic disk, a magnetic tape, a flash memory and a semiconductor memory. As a result of the processor 101 executing the analysis program, the computer 100 functions as the analysis device.

The input device 102 is a device for inputting information to the computer 100. Examples of the input device 102 include, but not limited to, a keyboard, a mouse and a touch panel.

The display device 103 is a device for displaying a picture image or a video image. Examples of the display device 103 include, but not limited to, an LCD (liquid-crystal display), a CRT (cathode-ray tube) and a PDP (plasma display). The display device 103 can display arbitrary information stored or created by the analysis device such as learning data, analysis data, shapelets “s” and an evaluation function “f”.

The communication device 104 is a device for computer 100 to perform wireless or wired communication with an external device. Examples of the communication device 104 include, but not limited to, a modem, a hub and a router.

The storage device 105 is a storage medium that stores, e.g., the OS of the computer 100, the analysis program, data necessary for execution of the analysis program and data created as a result of execution of the analysis program. Examples of the storage device 105 include a main storage device and an external storage device. Examples of the main storage device include, but not limited to, a RAM, a DRAM and a SRAM. Also, examples of the external storage device include, but not limited to, a hard disk, an optical disc, a flash memory and a magnetic tape. The learning data storage 1, the partial time series storage 2, the analysis data storage 3 and the parameter storage 4 may be formed in the storage device 105 or may be formed in an external server connected via the communication device 104.

The computer 100 may include one or more processors 101, one or more input devices 102, one or more display devices 103, one or more communication devices 104 and one or more storage devices 105, and peripheral devices such as a printer and a scanner may be connected to the computer 100.

Also, the analysis device may be configured by a single computer 100 or may be configured as a system including a plurality of computers 100 interconnected.

Furthermore, the analysis program may be stored in the storage device 105 of the computer 100 in advance, may be stored in a storage medium external to the computer 100 or may be uploaded on the Internet. In any case, as a result of the analysis program being installed in the computer 100 and executed, functions of the analysis device are provided.

Next, operation of the analysis device according to the present embodiment will be described in detail. In the below, it is assumed that at the start of operation, learning data (labeled data set T), a partial time-series set “G”, analysis data (unlabeled time-series data), an objective function and various parameters are provided in advance. Also, the objective function is expressed by the below expression.

$$\begin{matrix}[ Expression 2 ] & \\ {min}_{w , s , ρ} \frac{1}{ab} {\sum }_{i = 1 , … , α , j = 1 , … , b} l ( W , ( {X}_{i}^{+} ( S ) , {X}_{j}^{-} ( S ) ) , ρ ) - v ρ , subject to {‖ W ‖}_{1} \leq λ , ρ > 0. & ( 2 )\end{matrix}$$

In Expression (2), “λ” is a parameter that defines a space in which the weight vector “W” is regularized. “λ” affects the number of weight coefficients “w”, the number being not 0. ∥W∥₁≦λ is a regularization condition. Also, “ν” is an adjustment parameter related to generalization performance, and is set to be no less than 0 and no more than 1. The parameters “kλ”, “ν” are preferably determined so as to provide a maximum accuracy in scoring of the learning data. Set values of the parameters “λ”, “ν” are stored in the parameter storage 4.

Also, ρ (>0) is a scalar variable to be optimized, and is a parameter that indicates higher generalization performance for scoring as the parameter is larger. The parameter “ρ” corresponds to the other variable, which is described above, and is an object to be optimized by the objective function in addition to a weight vector “W” and a shapelet set “S”. Initial values of the parameter “ρ” and the weight vector “W” are stored in the parameter storage 4.

Also, “l” is a loss function and is expressed by the below expression.

[Expression 3]

l(W,(Xᵢ⁺,Xⱼ⁻),ρ)=max{ρ−W·Xᵢ⁺−W·Xⱼ⁻,0} (3)

The loss function “l” in Expression (3) is a pairwise hinge loss function. Use of the pairwise hinge loss function enables creation of an evaluation function “f” that enables highly-accurate calculation of a score according to a binary label.

Also, “X⁺” is a feature value vector “X” obtained from time-series data “t⁺” provided with a label of +1, and “X⁻” is a feature value vector “X” obtained from time-series data “t⁻” provided with a label of −1. The objective function in Expression (2) is intended to obtain f(X)=W·X that provides f(X⁺)−f(X⁻)>0 for as many pairs of feature value vectors “X⁺ⁿ”, “X⁻ⁿ” as possible.

Also, the parameter storage 4 stores set values of a learning rate “η”, which is a parameter in the stochastic gradient descent method. For the learning rate “η”, different values may be set for the respective variables. Also, a value of the learning “η” may vary according to the number of updates of the relevant variable. For example, it is known that where “c” is the number of updates of a variable, when updating the respective variables, generally, use of η=η/c or η=η/c^{1/2} enables easy obtainment of a converged optimum value.

The objective function is not limited to that described above and can arbitrarily set according to a purpose of the evaluation function “f”. For example, use of a hinge loss function, a logistic loss function or an ε-Incentive loss function as a loss function “l” enables creation of an evaluation function “f” for predicting a label. Also, use of a logistic loss function enables creation of an evaluation function “f” that is applicable to a logistic regression problem. Also, use of an ε-incentive loss function enables creation of an evaluation function “f” that is applicable to a regression problem for predicting a value of time-series data. Details of these loss functions are as described in the below document.
Reference: S. Shalev-Shwartz, Y. Singer, and N. Srebro, Pegasos: Primal Estimated sub-Gradient Solver for SVM, In Proceedings of the 24th International Conference on Machine Learning, ICML '07, pages 807-814, New York, N.Y., USA, 2007. ACM.

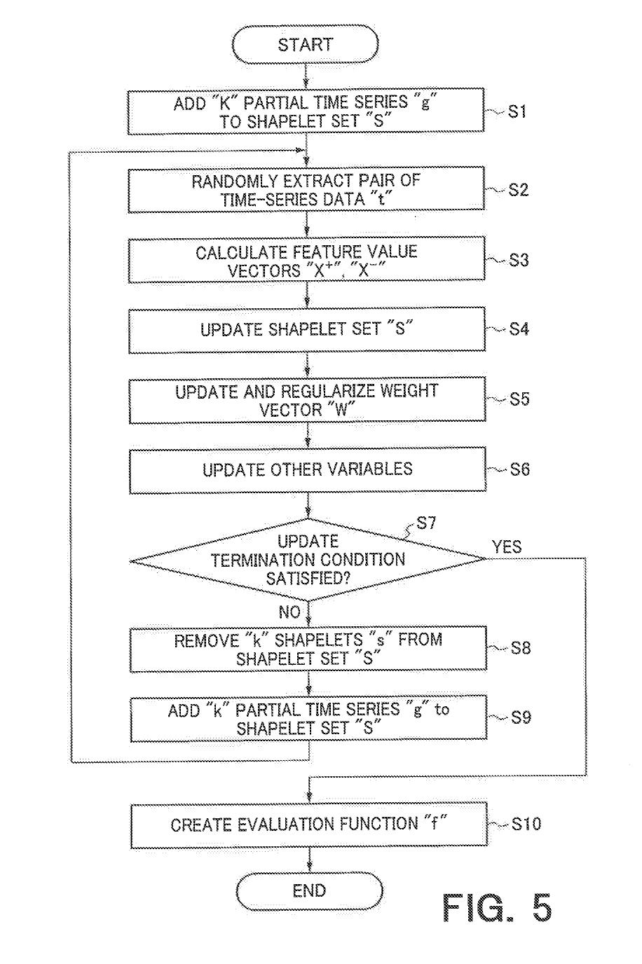

FIG. 5 is a flowchart illustrating an example of creating an evaluation function in the analysis device according to the present embodiment. As illustrated in FIG. 5, upon start of the creating processing, first, the adder 5 resets a shapelet set “S” to an empty set, extracts “K” partial time series “g” from the partial time series storage 2, and adds the extracted “K” partial time series “g” to the shapelet set “S” as shapelets “s” (step S1). The shapelet set “S” Includes the shapelets “sᵢ” (i=1 to K).

Next, the feature value calculator 6 randomly extracts a pair of time-series data “t⁺” provided with a label of +1 and time-series data “t⁻” provided with a label of −1 from the learning data storage 1 (step S2).

The feature value calculator 6 calculates feature value vectors “X⁺”, “X⁻” for the extracted time-series data “t⁺”, “t⁻”, respectively (step S3). Consequently, a pair of the feature value vectors “X⁺”, “X⁻” is obtained.

Here, if the loss function “l” is a hinge loss function, a logistic loss function or an ε-incentive loss function, the feature value calculator 6 may randomly extract one of the time-series data “t” and calculates a feature value vector “X” of the extracted time-series data “t”.

Subsequently, the shapelet updater 71 updates the shapelet set “S” based on the feature value vectors “X⁺”, “X⁻” and various parameters stored in the parameter storage 4 (step S4). More specifically, the shapelet updater 71 calculate a gradients of each shapelet “sᵢ,” according to the below expression.

[Expression 4]

∇ₛᵢ=−I(W·(X⁺−X⁻)<ρ)wᵢ(xₛᵢ⁺−xₛᵢ⁻) (4)

In Expression (4), “wᵢ” is a weight coefficient for a shapelet “sᵢ”, “x⁺” is a feature value of the shapelet “sᵢ” In the time-series data “t⁺”, and “x⁻” is a feature value of the shapelet “sᵢ” In the time-series data “t⁻”. Also, “I” is an indicator function, and if an input is true, returns 1, and if an Input is false, returns 0.

The shapelet updater 71 updates the shapelet sᵢ as below based on the gradient obtained according to Expression (4).

[Expression 5]

sᵢ=sᵢ−η∇sᵢ (5)

The shapelet updater 71 updates each of the “K” shapelets “sᵢ” (i=1 to K) included in the shapelet set “S” as described above. Consequently, the shapelet set “S” is updated.

Also, the weight coefficient updater 72 updates a weight vector “W” based on the feature value vectors “X⁺”, “X⁻” and various parameters stored in the parameter storage 4 (step S5). More specifically, the weight coefficient updater 72 calculates a gradient of the weight vector “W” according to the below expression.

[Expression 6]

∇_{w}=−I(W·(X⁺−X⁻)<ρ)(X⁺−X⁻) (6)

The weight coefficient updater 72 updates the weight vector “W” as below based on the gradient obtained according to Expression (6).

[Expression 7]

W=W−μ∇_{w} (7)

Then, regularizer 73 regularizes the updated weight vector “W” according to a regularization condition. In the example in Expression (2), the regularizer 72 performs “L1” regularization of the weight vector “W”.

Also, the other variable updater 74 updates the other variables based on the feature value vectors “X⁺ⁿ”, “X⁻ⁿ” and various parameters stored in the parameter storage 4 (step S6). In the example in Expression (2), the objective function includes a parameter “ρ” as another variable. Therefore, the other variable updater 74 calculates a gradient of the parameter “ρ” according to the below expression.

[Expression 8]

∇_{ρ}=I(W·(X⁺−X⁻)<ρ)−ν (8)

The other variable updater 74 updates the parameter “ρ” as below based on the gradient obtained according to Expression (8).

[Expression 9]

∇_{ρ}=ρ−η∇_{ρ} (9)

The shapelet set “S”, the weight vector “W” and the parameter “ρ” updated as described above are stored in the parameter storage 4. The order of steps S4 to S6 described above can arbitrarily be determined. Also, if no other variables are included in the objective function, step S6 is omitted.

Next, the determiner 8 determines whether or not an update termination condition is satisfied (step S7). The update termination condition is as described above.

If the update termination condition is not satisfied (NO in step S7), the remover 11 removes “k” shapelets “s”, corresponding weight coefficients “w” of which are 0, from the shapelet set “S” (step S8).

Then, the adder 5 randomly extracts “k” partial time series “g” from the partial time series storage 2 and adds the extracted “k” partial time series “g” to the shapelet set “S” as new shapelets “s” (step S9).

Subsequently, the processing for creating an evaluation function “f” returns to step S2. Subsequently, the processing in steps S2 to S9 is repeated until the update termination condition is satisfied.

On the other hand, if the update termination condition is satisfied (YES in step S7), the evaluation function creator 9 creates an evaluation function “f” based on the shapelet set “S” and the weight vector “W” stored in the parameter storage 4 at that time (step S10). The evaluation function “f” is expressed by, for example, the Inner product of the weight vector “W” and the feature value vector “X” for the shapelet set “S”.

As described above, in the present embodiment, the respective parameters are updated based on time-series data “t” randomly selected in each update processing, and a solution of the objective function is obtained. This optimization algorithm corresponds to what is called a stochastic gradient descent method. In other words, in the present embodiment, an evaluation function “f” is created using a stochastic gradient descent method.

The analyzer 10 performs analysis of analysis data using the evaluation function “f” created as described above. Consequently, the analyzer 10 can provide a high (or low) score to time-series data whose label is estimated to be +1 and provide a low (or high) score to time-series data whose label is estimated to be −1.

As described above, the analysis device according to the present embodiment can create an evaluation function “f” by performing update processing on “K” shapelets “s” a plurality of times. Where the number of times of update processing is “n” (<<N), the number of time-series data “t” used for creating the evaluation function “f” is “n”. Also, it is assumed that a time series length of each time-series data is “L”. In this case, a calculation amount for creating the evaluation function “f” in the present embodiment is “O” (K×n×L). Therefore, the present embodiment enables substantial reduction in calculation amount for creating an evaluation function “f” and thus enables provision of an analysis device with a calculation amount reduced.

Also, the analysis device according to the present embodiment creates an evaluation function “f” using randomly-selected “K” partial time series “g” as shapelets “s”. Therefore, an evaluation function “f” can be created based on an arbitrary labeled data set “T”, without “K” random shapelet candidates being provided.

Also, the analysis device according to the present embodiment crates an evaluation function “f” based on a shapelet set “S” with shapelets “s”, corresponding weight coefficients “w” of which are 0, removed. Consequently, independence of each shapelet “s” Included in the shapelet set “S” is enhanced, enabling creation of an evaluation function “f” with high prediction accuracy.

Time-series data to be analyzed by the analysis device according to the present embodiment may be, for example, time-series data from various sensors installed in manufacturing devices and the like. Analysis of time-series data from a sensor by the analysis device enables creation of shapelets and an evaluation function for detecting an abnormality in a manufacturing device or the like. Analysis of current time-series data from the sensor using the shapelets and the evaluation function enables real-time detection of an abnormality in the manufacturing device or the like. Use of the analysis device according to the present embodiment enables high-speed analysis even if the time-series data has a very long time series length (for example, a sampling rate is high or processing time is long).

Also, e.g., an energy demand can be indicated by time-series data. Therefore, learning data obtained by providing labels indicating demand statuses such as a high demand, a low demand and an ordinary demand to the time-series data is provided, and the learning data is analyzed by the analysis device, enabling creation of shapelets and an evaluation function for estimating a demand status such as an energy demand. Providing labels to current time-series data using the shapelets and the evaluation function enables estimation of a current demand state, which can be used for adjustment of electricity supply. Use of the analysis device according to the present embodiment enables high-speed analysis even if a span of measurement of, e.g., a demand (e.g., one day or one week) is long.

Also, learning data obtained by providing labels indicating states and actions of humans such as standing, walking and sleeping to time-series data from a biosensor such as an accelerometer is provided, and the learning data is analyzed by the analysis device, enabling creation of shapelets and an evaluation function for estimating a state or an action of a human. Providing labels to current time-series data using the shapelets and the evaluation function enables estimation of a current status or action, which can be used for, e.g., medical practice. Use of the analysis device according to the present embodiment enables high-speed analysis even in the case of a biosensor having a very high sampling rate.

In the present embodiment, update of various parameters by the parameter updater 7 may be performed by batch processing. In this case, in step S2, the feature value calculator 6 extracts a plurality of the pairs and calculates a pair of feature value vectors “X⁺”, “X⁻” for each of the extracted pairs. Then, in steps S4 to S6, the parameter updater 7 updates the shapelet set “S”, the weight vector “W” and the other variables based on each of the pairs of feature value vectors “X⁺”, “X⁻”. In other words, the respective parameters are updated a plurality of times in one update process. Consequently, the number of times of update processing can be reduced.

### Second Embodiment

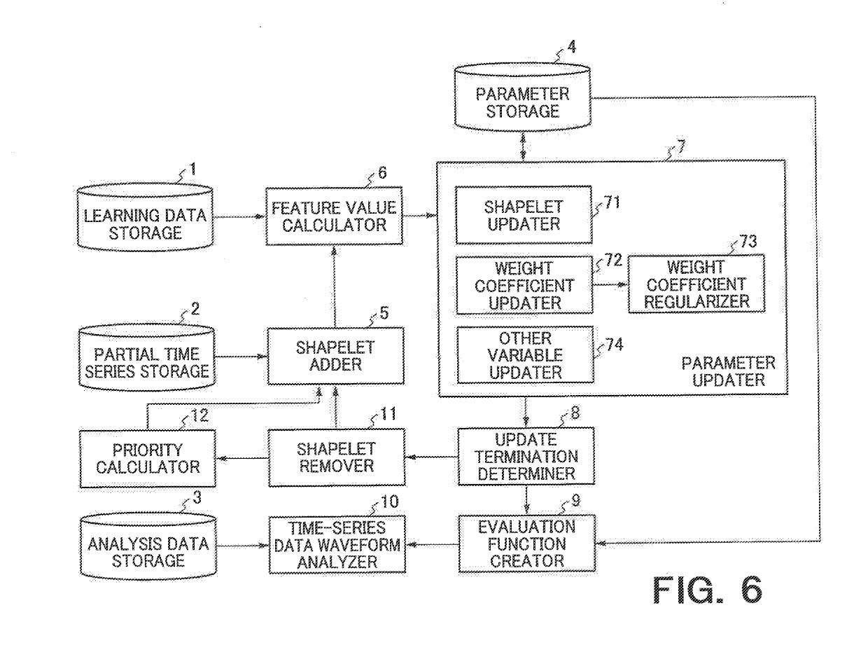

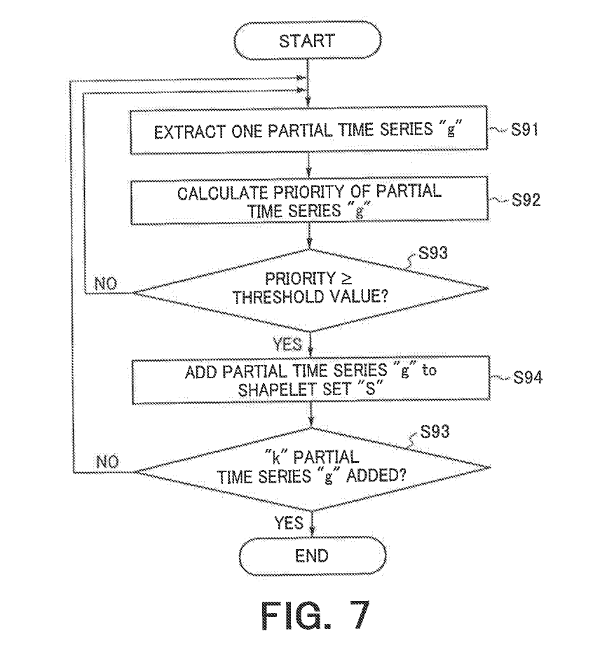

An analysis device according to a second embodiment will be described with reference to FIGS. 6 and 7. In the present embodiment, “k” partial time series “g” are added to a shapelet set “S” In order of priority as shapelets “s”. FIG. 6 is a diagram Illustrating an example of a functional configuration of an analysis device according to the present embodiment. The analysis device in FIG. 6 includes a priority calculator 12. The rest of the configuration of the analysis device in FIG. 6 is similar to that in FIG. 1. Also, a hardware configuration of the analysis device according to the present embodiment is similar to that of the first embodiment.

The priority calculator 12 calculates priorities of the partial time series “g”. A priority of a partial time series “g” is a value indicating a non-similarity of the partial time series “g” to a shapelet “s” removed by a remover 11 from the shapelet set “S”. The priority calculator 12 calculates a higher priority as the non-similarity is higher. In other words, a priority of a partial time series “g” is higher as the partial time series “g” has a higher non-similarity to the removed shapelet “s”.

As the non-similarity, for example, a feature value can be used. As the feature value is larger, the non-similarity is higher. In this case, the priority calculator 12 may calculate a feature value of a partial time series “g” relative to the removed shapelet “s”, and calculate a higher priority as the obtained feature value is larger.

If there are a plurality of removed shapelets “s”, the priority calculator 12 may calculate a largest value, a smallest value or an average value of priorities of a partial time series “g” relative to the respective shapelet “s” as a priority of the partial time series “g”.

In the present embodiment, an adder 5 adds partial time series “g” whose priority calculated by the priority calculator 12 is high to the shapelet set “S” as shapelets “s”. A method for the addition will be described in detail later.

Next, operation of the analysis device according to the present embodiment will be described. FIG. 7 is a flowchart Illustrating an example of processing for adding partial time series “g” in the analysis device according to the present embodiment. The flowchart in FIG. 7 corresponds to internal processing in step S9 In FIG. 5. Here, steps other than step S9 in a processing for creating an evaluation function “f” in the present embodiment are similar to those in FIG. 5.

In the present embodiment, upon the remover 11 removing “k” shapelets “s” from a shapelet set “S” (step S8), as Illustrated in FIG. 7, the adder 5 randomly extracts one partial time series “g” from a partial time series storage 2 (step S91). Next, the priority calculator 12 calculates a priority of the extracted partial time series “g” (step S92). Subsequently, the adder 5 determines whether or not the priority of the partial time series “g” is no less than a preset threshold value (step S93).

If the priority is less than the threshold value (NO in step S93), the processing returns to step S91.

On the other hand, if the priority is no less than the threshold value (YES in step S93), the adder 5 adds the partial time series “g” extracted in step S91 to the shapelet set “S” as a shapelet “s” (step S94).

Subsequently, the adder 5 determines whether or not “k” partial time series “g” have been added to the shapelet set “S” (step S95). If “k” partial time series “g” have not been added (NO in step S95), the processing returns to step S91. On the other hand, if “k” partial time series “g” have been added (YES in step S95), the processing for adding partial time series “g” ends. Subsequently, an evaluation function “f” is created based on the shapelet set “S” with partial time series “s” with high priorities added.

As described above, the analysis device according to the present embodiment creates an evaluation function “f” based on a shapelet set “S” with shapelets “s” (partial time series “g”) with high priorities instead of shapelets “s”, corresponding weight coefficients “w” of which are 0. Consequently, Independence of each shapelet “s” Included in the shapelet set “S” is further enhanced, enabling creation of an evaluation function “f” with a high prediction accuracy.

Here, the extraction of the partial time series “g” and the priority calculation may be performed by a batch process. In this case, in step S91, the adder 5 extracts a plurality of partial time series “g”, and in step S92, the priority calculator 12 calculates priorities of the plurality of partial time series “g” extracted.

Also, in the present embodiment, the priority calculator 12 may calculate, in advance, priorities of a part or all of partial time series “g” stored in the partial time series storage 2. In this case, the adder 5 may add “k” partial time series “g” in descending order of priority from among the partial time series “g” whose priorities have been calculated, to the shapelet set “S”. The addition of the partial time series “g” as described above enables the partial time series “g” to be added to the shapelet set “S” in descending order of priority.

While certain embodiments have been described, these embodiments have been presented by way of example only, and are not Intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A time-series data waveform analysis device implemented by a computer including at least one hardware processor:
the hardware processor configured to:
add a shapelet being a part of a partial time series included in labeled time-series data to a shapelet set;
randomly extract one or more labeled time-series data and calculate a feature value of the shapelet for the extracted labeled time-series data according to a TSS method;
update a parameter, which includes the shapelet and a weight coefficient for the shapelet, based on the feature value according to a stochastic gradient descent method;
remove the shapelet, the corresponding weight coefficient of which is 0, from the shapelet set; and
create an evaluation function based on the shapelet in the shapelet set and the weight coefficient.

2. The time-series data waveform analysis device according to claim 1, wherein the hardware processor is configured to calculate a gradient of the parameter based on the feature value and update the parameter based on the gradient.

3. The time-series data waveform analysis device according to claim 1, wherein the feature value is a minimum value of an average distance between the shapelet and the labeled time-series data.

4. The time-series data waveform analysis device according to claim 1, the hardware processor is configured to analyze unlabeled time-series data based on the evaluation function.

5. The time-series data waveform analysis device according to claim 1, wherein the hardware processor is configured to regularize the weight coefficient based on a predetermined regularization condition.

6. The time-series data waveform analysis device according to claim 1, the hardware processor is configured to determine whether or not to terminate the update of the parameter based on the number of updates or an accuracy of the evaluation function.

7. The time-series data waveform analysis device according to claim 1, the hardware processor is configured to calculate a priority according to a non-similarity between the shapelet, the corresponding weight coefficient of which is 0, and the partial time series included in the labeled time-series data.

8. A time-series data waveform analysis method:
adding a shapelet being a part of a partial time series included in labeled time-series data to a shapelet set;
randomly extracting one or more labeled time-series data and calculate a feature value of the shapelet for the extracted labeled time-series data according to a TSS method;
updating a parameter, which includes the shapelet and a weight coefficient for the shapelet, based on the feature value according to a stochastic gradient descent method;
removing the shapelet, the corresponding weight coefficient of which is 0, from the shapelet set; and
creating an evaluation function based on the shapelet in the shapelet set and the weight coefficient.

9. A non-transitory computer readable medium having a computer program stored therein which when executed by a computer, causes the computer to perform processes of steps comprising:
adding a shapelet being a part of a partial time series included in labeled time-series data to a shapelet set;
randomly extracting one or more labeled time-series data and calculate a feature value of the shapelet for the extracted labeled time-series data according to a TSS method;
updating a parameter, which includes the shapelet and a weight coefficient for the shapelet, based on the feature value according to a stochastic gradient descent method;
removing the shapelet, the corresponding weight coefficient of which is 0, from the shapelet set; and
creating an evaluation function based on the shapelet in the shapelet set and the weight coefficient.
